(19) United States
(12) Patent Application Publication
(10) Pub. No.: US 2025/0141425 A1
(43) Pub. Date: May 1, 2025

(54) ACOUSTIC RESONATOR DEVICES OPERATING AT HIGH-ORDER MODES

(71) Applicant: Avago Technologies International Sales Pte. Limited, Singapore (SG)

(72) Inventors: Stephan Marksteiner, München (DE); Winfried Nessler, München (DE); Andriy Yatsenko, Vaterstetten (DE)

(21) Appl. No.: 18/498,011

(22) Filed: Oct. 30, 2023

(51) Int. Cl. H03H 9/13; H03H 9/02; H03H 9/17

(52) U.S. Cl. CPC H03H 9/132; H03H 9/02015; H03H 9/171

(57) ABSTRACT

The subject technology is related to acoustic resonators. More specifically, an embodiment of the subject technology provides an acoustic resonator device that includes a piezoelectric layer disposed between a first electrode and a second electrode. The total thickness of the first electrode, the second electrode, and the third electrode allows the device to operate according to a second (or higher order) thickness extension mode. There are other embodiments as well.

### FIELD OF INVENTION

The subject technology is directed to acoustic resonator devices.

### BACKGROUND OF THE INVENTION

Acoustic resonators have a wide range of implementations and applications. One of the acoustic resonator implementations is film bulk acoustic resonators. Bulk acoustic wave resonators (BAW) and their various configurations such as film bulk acoustic resonators (FBARs), solidly mounted resonators (SMRs), and reverse-stacked FBARs (RSBARs) provide wide application in communication systems, particularly in filters for radio frequency (RF) signal processing. The continuous downsizing of technology and the advent of 5G and beyond communication networks have created the need for compact, efficient, and high-performance filtering solutions.

In existing approaches, FBAR devices include a piezoelectric layer sandwiched between two electrodes and are typically designed to operate at a particular resonant frequency, which is determined by the physical dimensions and material properties of the resonator. The resonators are employed to either allow signals at the resonant frequency to pass through or to reject them, thereby providing filtering functionality. Unfortunately, existing acoustic resonators are inadequate for the reasons provided below. New and improved acoustic resonator devices are desired.

### BRIEF DESCRIPTION OF THE DRAWINGS

FIG. 1 is a simplified diagram illustrating a resonator operating at a first thickness extension mode.

FIG. 2A is a simplified diagram illustrating resonator 200 operating at a third thickness extension mode according to embodiments of the subject technology.

FIG. 2B is a graph illustrating operation of resonator 200.

FIG. 3A is a simplified diagram illustrating resonator 300 operating at a third thickness extension mode according to embodiments of the subject technology.

FIG. 3B is a graph illustrating operation of resonator 300.

FIG. 4 is a simplified diagram illustrating resonator 400 comprising two piezoelectric layers according to embodiments of the subject technology.

FIG. 5A is a simplified diagram illustrating resonator 500 comprising two piezoelectric layers and bilayer electrodes according to embodiments of the subject technology.

FIG. 5B is a graph illustrating operation of resonator 500.

FIG. 6 is a simplified diagram illustrating resonator 600 comprising two piezoelectric layers separated by an electrode according to embodiments of the subject technology.

FIG. 7 is a simplified diagram illustrating resonator 700 comprising two piezoelectric layers separated by layers of electrode material according to embodiments of the subject technology.

### DETAILED DESCRIPTION OF THE INVENTION

The subject technology is related to acoustic resonators. More specifically, an embodiment of the subject technology provides an acoustic resonator device that includes a piezoelectric layer disposed between a first electrode and a second electrode. The thickness of the first electrode and the second electrode allows the device to operate according to a second (or higher order) thickness extension mode. There are other embodiments as well.

In the context of resonator design, the electrodes play a crucial role in determining resonator performance and characteristics. For example, resonant frequencies, bandwidth of a mode, electrical losses, and device dimensions are important characteristics. As an example, the bandwidth of a mode may be defined by the separation between its parallel and series resonance frequencies, represented by the formula bw=fp−fs. Various existing FBAR designs provide resonators that utilize relatively thin electrodes operating at a first thickness extension mode, which facilitates certain operational characteristics. However, this approach has limits in managing the stress waves within the electrodes and can affect electrical conductance and bandwidth, amongst other performance metrics. As technology advances towards higher frequencies and miniaturization, managing electrode characteristics, especially thickness, becomes a challenging task, demanding a meticulous balance between electrical and mechanical properties.

The resonant frequency of an FBAR is-roughly speaking-inversely proportional to the total thickness of the resonator stack. To achieve higher operational frequencies, it involves the reduction of the layer thickness. For example, the electrode's thinness is also important in ensuring that it does not significantly impact the overall thickness and hence, the resonant frequency. However, thinner electrodes, while facilitating high-frequency operation, are susceptible to reduced electrical conductance. Additionally, for high frequency operations (e.g., 5 GHz and above), manufacturing electrodes thin enough for high frequency becomes a challenge. Ensuring a high yield in the manufacturing process of high frequency FBAR, while maintaining requisite performance parameters, can be economically and technologically challenging.

It is to be appreciated that embodiments of subject technology provide acoustic resonator devices that operate at high frequencies (e.g., over 5 GHz) without significantly reducing electrode thickness (e.g., an electrode being no thinner than 100 nm). For example, different electrode thickness and composition (e.g., aluminum and tungsten) may be used, depending on the implementation, which allows for diverse acoustic impedance and mechanical properties, providing a platform to tune the device for optimal bandwidth (e.g., fp−fs), electrical performance, and resonance characteristics, potentially increasing the device's efficiency and performance across various applications. With a total thickness allowing for multiple stress maxima disposed within an FBAR stack, the device may exhibit improved acoustic and electrical performance during operation. This could enhance the usability of the device, especially in high-frequency applications.

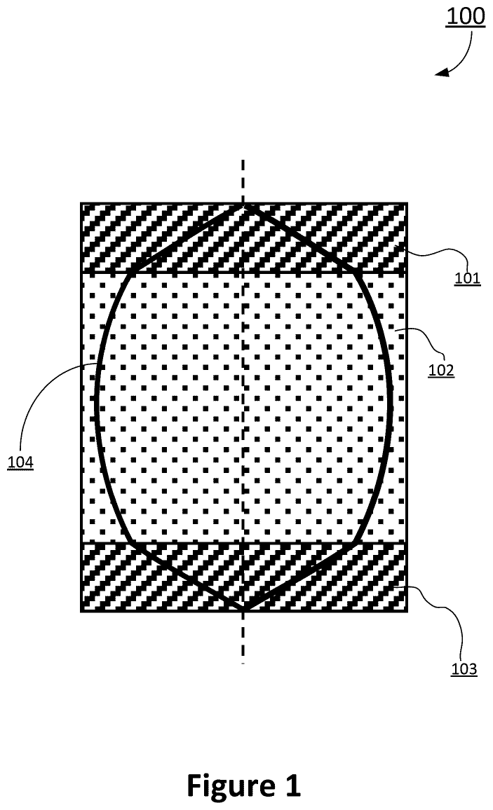

Various embodiments according to prior art provide frequency filters that utilize FBAR resonators to operate at high frequencies, such as 12 GHz. These filters can function within a range of 3 to 20 GHz and potentially beyond. The resonators, in some existing approaches, operate in the TE1 mode and are scaled down in layer thickness to achieve the desired 12 GHz frequency. These resonators are engineered to operate with a single acoustic stress maximum located within the piezo layer. The stress gradually reduces to zero towards both the lower and upper surfaces, see FIG. 1. The operating frequency is defined by matching one stress half wave along the z-axis between the lower and upper surfaces. This mode of operation is referred to as the first thickness extensional mode, TE1, or fundamental mode.

It is to be appreciated that embodiments according to the subject technology allow for the thickness of one or, optionally, both electrode layers to operate with additional stress half-waves within the respective electrode layer. For example, configurations with one or more thick electrodes introduce additional stress zero(es) disposed within the stack, thereby allowing for operations at high frequencies while using relatively thick (compared to resonators operating in TE1 mode) electrodes. This consequently leads to improved electrical conductance and structural strength. For example, an exemplary implementation involving one electrode being thickened results in a film bulk acoustic resonator (FBAR) operating in TE2 mode, whereas the thickening of both electrodes allows for the FBAR to operate in TE3 and/or higher order mode.

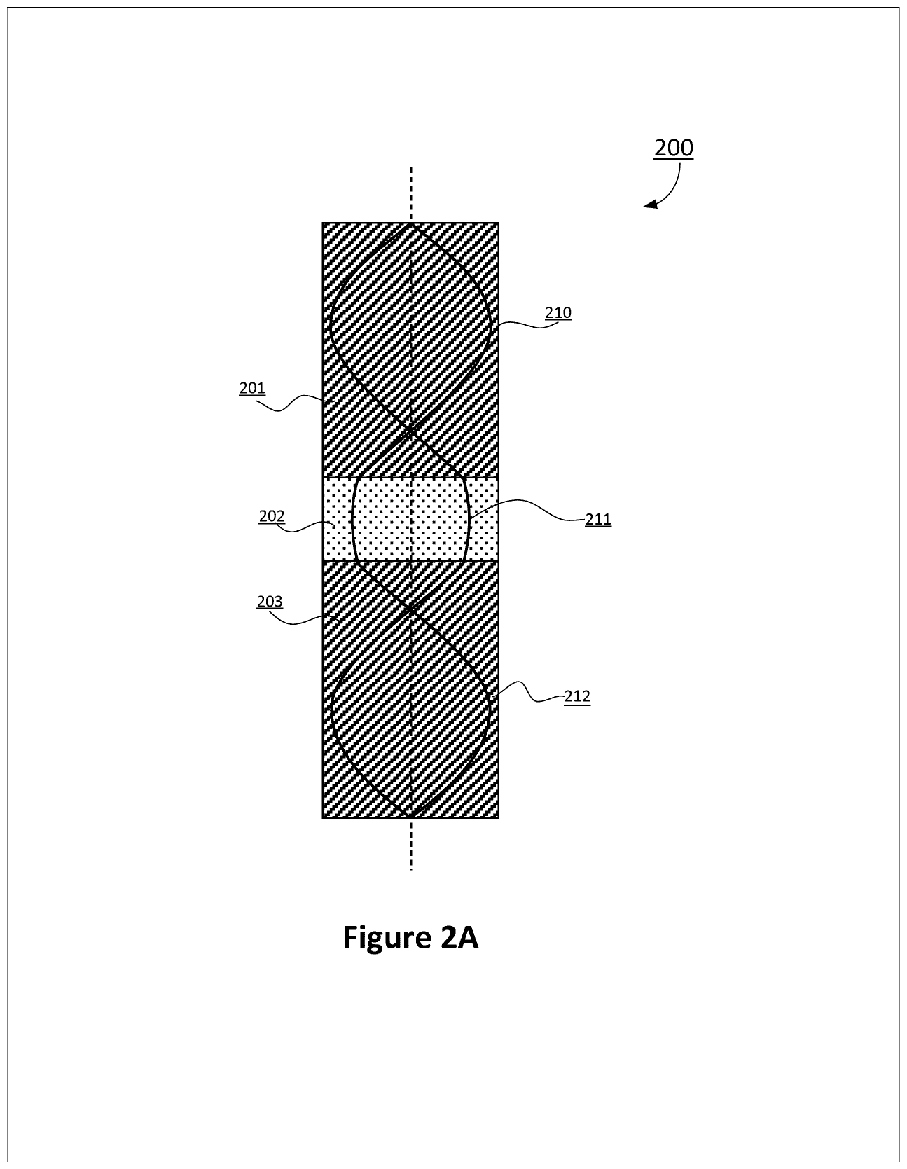

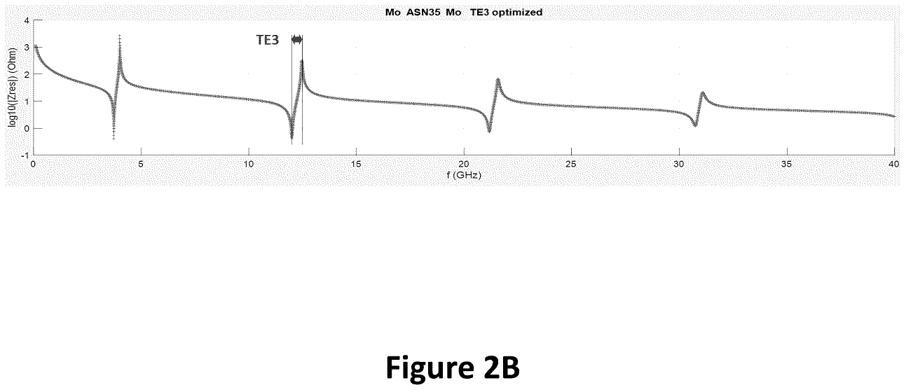

According to various embodiments, FBAR operating in TE3-mode is configured to resonate at a predefined operating frequency by incorporating two additional stress zero points within its layer stack. The operating frequency is determined by allowing for three half-waves of stress along its z-axis. This mode of operation is designated as third thickness extensional mode, or TE3. By matching three—as opposed to a single half-wave—between the upper and lower surfaces, resonator design is afforded the latitude to configure FBAR stack with approximately threefold thickness—maintaining the same operating frequency. Subsequently, the two supplementary stress peaks are strategically disposed within the thickened electrode layers, thereby ensuring substantially enhanced electrical conductance (see FIG. 2A, also refer to page 6 for a detailed exposition).

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the subject technology is not intended to be limited to the embodiments presented, but is to be accorded the widest scope consistent with the principles and novel features disclosed herein.

In the following detailed description, numerous specific details are set forth in order to provide a more thorough understanding of the subject technology. However, it will be apparent to one skilled in the art that the subject technology may be practiced without necessarily being limited to these specific details. In other instances, well-known structures and devices are shown in block diagram form, rather than in detail, in order to avoid obscuring the subject technology.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

When an element is referred to herein as being “disposed” in some manner relative to another element (e.g., disposed on, disposed between, disposed under, disposed adjacent to, or disposed in some other relative manner), it is to be understood that the elements can be directly disposed relative to the other element (e.g., disposed directly on another element), or have intervening elements present between the elements. In contrast, when an element is referred to as being “disposed directly” relative to another element, it should be understood that no intervening elements are present in the “direct” example. However, the existence of a direct disposition does not exclude other examples in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, the existence of direct bonding does not exclude other forms of bonding, in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

FIG. 1 is a simplified diagram illustrating a resonator operating at a first thickness extension mode. In a pursuit to achieve operation at a target frequency (e.g., 12 GHz), the resonators are scaled down in layer thickness. Designed to operate with a singular acoustic stress maximum located within the piezoelectric layer, resonator 100 includes top electrode 101, piezoelectric layer 102, and bottom electrode 103. Here, the stress monotonically decays to zero towards both the lower and upper surfaces of the device, with one stress half wave matched along the z-axis between these surfaces, defining its operating frequency. This mode of operation is referred to as fundamental thickness extension mode (i.e., TE1) and involves a single stress wave 104 extending through the entire thickness of resonator 100, encompassing electrodes 101 and 103 as well as piezoelectric layer 102. The wavelength of stress wave 104 determines the resonator's operating frequency. Achieving high frequencies, such as 12 GHz, necessitates extremely thin layer stacks, and critically, very thin electrodes which are characterized by poor electrical conductance.

FIG. 2A is a simplified diagram illustrating resonator 200 operating at a third thickness extension mode according to embodiments of the subject technology. This diagram is merely an example, which should not unduly limit the scope of the claims. One of ordinary skill in the art would recognize many variations, alternatives, and modifications. Resonator 200 is configured to operate in third thickness extension mode (TE3), characterized by three distinct acoustic stress maxima. Within its structure, resonator 200 includes top electrode 201, piezoelectric layer 202, and bottom electrode 203. The acoustic stress maxima are strategically positioned: maxima 210 is positioned within top electrode 201, maxima 211 is positioned within piezoelectric layer 202, and maxima 212 is positioned within bottom electrode 203.

Thickening one or both electrode layers allows extra stress half-wave(s) to reside within the electrode layer(s). For example, increased thickness introduces additional stress zeroes within the stack and enables high frequencies to be achieved with notably thicker electrodes, resulting in significantly enhanced electrical conductance. For example, when only one of the two electrodes is thickened, the resonator operates in the second thickness extension (TE2) mode; if both are electrodes thickened, it operates in the third thickness extensional (TE3) mode. For example, electrode layers are configured to be sufficiently thick so that additional stress field maxima be accommodated within them. In various implementations, the design of the stack is optimized to secure the necessary bandwidth in the new operational mode—TE2 when thickening one electrode, and TE3 when both are thickened, with the ensuing discussion predominantly focusing on the latter scenario. An acoustic resonator designed to operate in TE3 mode resonates at a defined operating frequency by incorporating two additional stress zeros within the stack. It dictates its operating frequency by accommodating three stress half-waves along its z-axis, synonymous with the TE3 mode of motion. The ability to match three, rather than one, half-waves between the upper and lower surfaces permits the stack to be designed approximately three times thicker while maintaining the same operating frequency. As shown, the two additional stress maxima are located within the electrode layers.

These three stress waves, identified by their respective maxima 210, 211, and 212, facilitate the resonator's operation at high frequencies (e.g., 12 GHz). For desired performance, the materials used for electrodes 201 and 203 are selected based on their acoustic impedance, tailoring them for specific applications. In an embodiment, electrodes 201 and 203 comprise molybdenum, and other metal materials may be used as well. For example, layer 202 comprises a piezoelectric material, which generates an electric charge in response to applied mechanical stress. For example, layer 202 may include aluminum nitride (AlN), aluminum-scandium nitride (ASN), which is a type of piezoelectric material that comprises a solid solution of and scandium nitride (ScN). For example, the formula for ASN is Al₁₋ₓScₓN, where x represents the proportion of scandium. Other piezoelectric materials may be used as well, which may be used for high-frequency applications such as signal filtering where energy conversion efficiency is important. Piezoelectric material may also include zinc oxide, lead zirconate, barium strontium titanate, lithium niobate, lithium tantalate, and/or others.

Furthermore, electrode thickness is important in resonator design. While thin electrodes can present issues like reduced conductivity and compromised mechanical rigidity, resonator 200 addresses this by featuring electrodes 201 and 203 with a substantial thickness of approximately 3000 angstroms. In comparison, piezoelectric layer 202 may have a thickness of about 1000 angstroms. It is to be appreciated that other thicknesses are possible as well.

FIG. 2B is a graph illustrating operation of resonator 200. As shown in FIG. 2B, operation of resonator 200 in TE3 mode is at about 12 GHz, with both great frequency response and bandwidth (e.g., bandwidth of about 250-500 MHz)

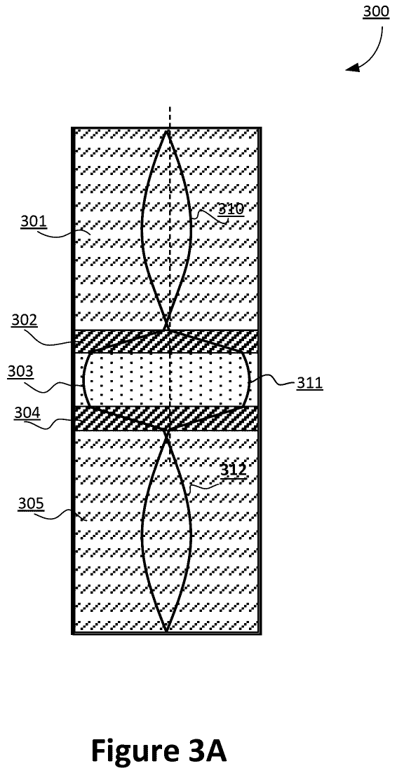

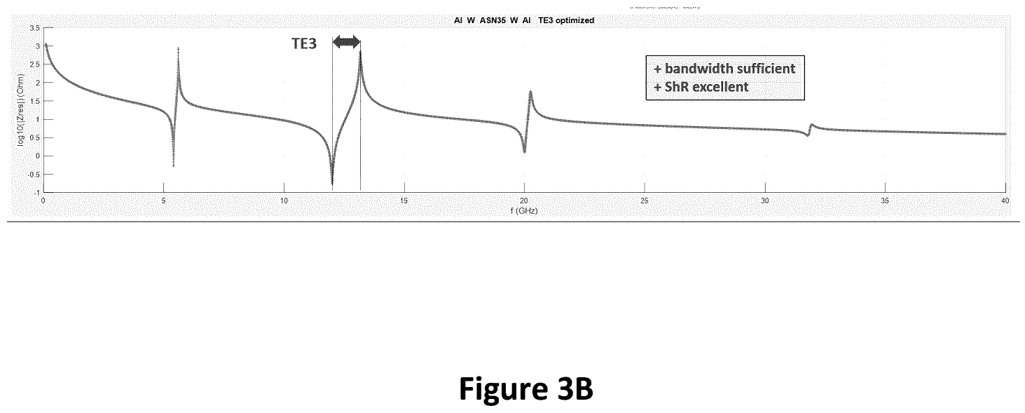

FIG. 3A is a simplified diagram illustrating resonator 300 operating at a third thickness extension mode according to embodiments of the subject technology. This diagram is merely an example, which should not unduly limit the scope of the claims. One of ordinary skill in the art would recognize many variations, alternatives, and modifications. Resonator 300 includes a top bilayer electrode, a bottom bilayer electrode, and a piezoelectric layer 303 disposed between the top bilayer electrode and the bottom bilayer electrode. The top bilayer electrode includes metal layer 301 and metal layer 302. For example, metal layer 301 comprises aluminum material, and metal layer 302 includes tungsten material. It is understood that other materials are possible as well. For example, different metal layers—as part of a bilayer electrode—are characterized by different acoustic impedance and electric conductance.

For example, tungsten layers (e.g., layer 302 and layer 304) serve as acoustic mirror layers that reduce stress field in high conducting Al layers. For example, metal layers 302 and 304 (e.g., acting as acoustic mirror layers) may be considerably thinner (e.g., around 360 angstroms) than metal layers 301 and 305 (e.g., aluminum layers with about 2500 angstroms thickness), while the piezoelectric layer is characterized by a thickness of about 800 angstroms. Depending on the metal layer materials and their characteristics, other thicknesses may be possible as well. For example, as resonator 300 operates in the third thickness extension mode (i.e., TE3), three stress waves are positioned as shown in FIG. 3A; stress wave 310 is positioned within layer 301; stress wave 311 is positioned within layers 302, 303, and 304; stress wave 312 is positioned within layer 305.

FIG. 3B is a graph illustrating operation of resonator 300. As shown in FIG. 3B, operation of resonator 300 in TE3 mode is at about 12 GHz, with both great frequency response and bandwidth (e.g., bandwidth about 1150 MHz).

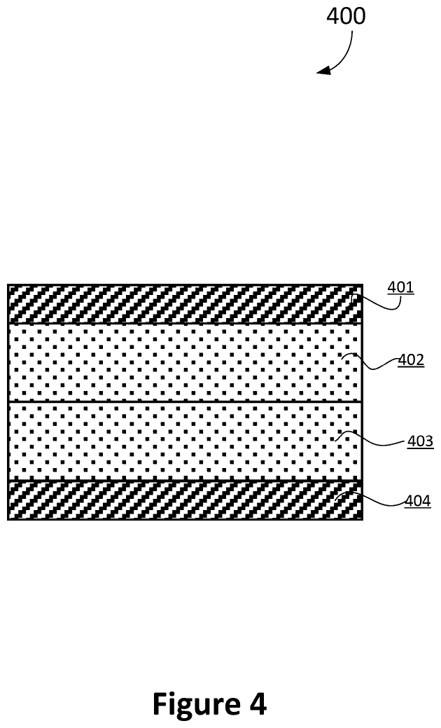

FIG. 4 is a simplified diagram illustrating resonator 400 comprising two piezoelectric layers according to embodiments of the subject technology. This diagram is merely an example, which should not unduly limit the scope of the claims. One of ordinary skill in the art would recognize many variations, alternatives, and modifications. Resonator 400 comprises two layers (i.e., 402 and 403) of piezoelectric material disposed between electrode 401 and electrode 404. The two piezo layers have opposing c-axis orientations, as explained below in paragraph 0045.

In an embodiment, electrodes 401 and 404 comprise molybdenum, and other metal materials may be used as well.

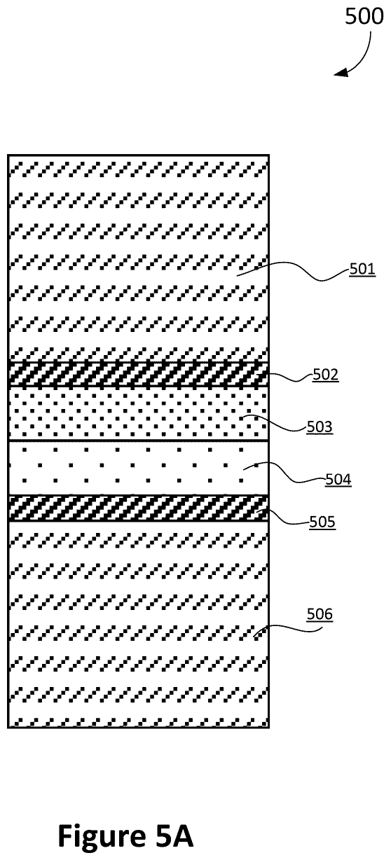

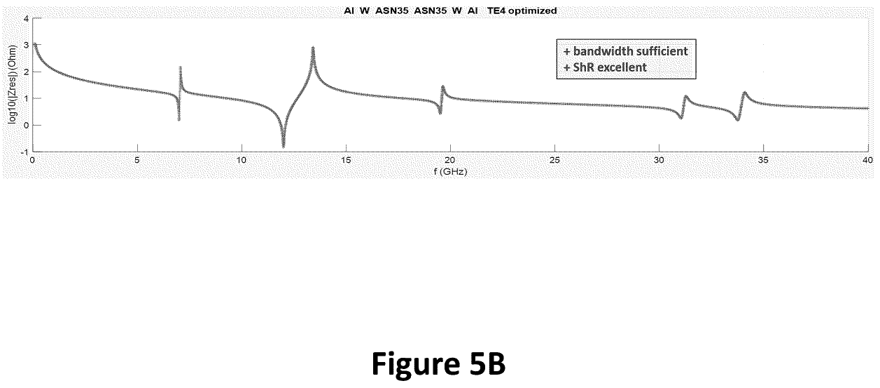

FIG. 5A is a simplified diagram illustrating resonator 500 comprising two piezoelectric layers and bilayer electrodes according to embodiments of the subject technology. This diagram is merely an example, which should not unduly limit the scope of the claims. One of ordinary skill in the art would recognize many variations, alternatives, and modifications. Resonator 500 includes a top bilayer electrode that includes layer 501 and layer 502. Resonator 500 also includes a bottom bilayer electrode that includes layer 505 and layer 506. Piezoelectric layers 503 and 504 are disposed between the top bilayer electrode and the bottom bilayer electrode. As an example, layer 501 comprises aluminum material, and layer 502 comprises tungsten material. Similarly, layer 506 comprises aluminum material, and layer 505 comprises tungsten material. Aluminum and tungsten electrode layers—based on their acoustic and electric characteristics—are configured at different thicknesses, as explained above. For example, aluminum electrode layers (e.g., layers 501 and 506) are characterized by a thickness of about 2500 angstroms, and tungsten electrode layers (e.g., layers 502 and 505) are characterized by a thickness of about 480 angstroms.

Piezoelectric layers 503 and 504, in various implementations, comprise the same piezoelectric material (e.g., ASN material), but configured in different directions. For example, layer 503 is configured with a reverse c-axis direction relative to that of layer 504. For example, the term “c-axis” refers to a specific orientation axis in the growth of thin piezoelectric films, which is tied to electrical and mechanical responses. When a piezoelectric film is developed on a bottom electrode, which is designated as the electrical ground and datum growth surface, the c-axis can be either positively or negatively oriented in relation to this datum surface. A positive c-axis orientation implies that it points upward from the datum, aligning with a positively applied E-field towards the top electrode. On the other hand, a negative c-axis orientation implies it points downward, towards the datum surface. Consequently, when a positive voltage is applied to a film with a positive c-axis, it compresses (Type CP, “Compression Positive”). If a negative voltage is applied to a film with a negative c-axis, it also compresses (Type CN, “Compression Negative”). For example, layer 504 is configured as compressive positive, and layer 503 is configured as compression negative, according to various embodiments of the invention. Because piezoelectric materials are anisotropic and have different properties at different axes, when two layers of piezoelectric material of different orientations are stacked as shown in FIG. 5, the configuration can yield a parallel connection that increases resonator impedance. For example, layers 503 and 504 are configured at a thickness of about 1800 angstroms each. In various embodiments, resonator 500 is configured to operate at the fourth thickness extension (TE4) mode.

FIG. 5B is a graph illustrating operation of resonator 500. Depending on the implementation, resonator 500 may operate in TE2 mode at about 7 GHz or TE4 mode at about 12 GHz. When operating at 12 GHz in TE4 mode, resonator 500 is characterized by a large bandwidth of about 1.4 GHz (compared to about 67 MHz at TE2 mode). Additionally, resonator 500 is characterized by a low sheet resistance, at about 0.196 Ohm square, both in TE2 and TE4 modes.

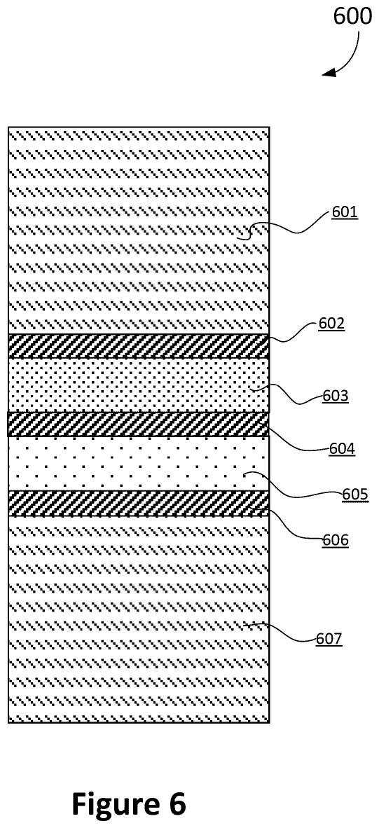

FIG. 6 is a simplified diagram illustrating resonator 600 comprising two piezoelectric layers separated by an electrode according to embodiments of the subject technology. This diagram is merely an example, which should not unduly limit the scope of the claims. One of ordinary skill in the art would recognize many variations, alternatives, and modifications. Resonator 600 includes a top bilayer electrode that includes layer 601 and layer 602. Resonator 600 also includes a bottom bilayer electrode that includes layer 606 and layer 607. Piezoelectric layers 603 and 605 are disposed between the top bilayer electrode and the bottom bilayer electrode. Electrode layer 604 is disposed between piezoelectric layers 603 and 605. As an example, layer 601 comprises aluminum material, and layer 602 comprises tungsten material. Similarly, layer 607 comprises aluminum material, and layer 606 comprises tungsten material. Electrode layer 604, disposed between two piezoelectric layers (characterized by different orientations), may comprise tungsten material according to an embodiment of the subject technology. Aluminum and tungsten electrode layers—based on their acoustic and electric characteristics—are configured at different thicknesses, as explained above. As shown in FIG. 6, aluminum electrode layers are thicker than tungsten electrode layers, for the reasons provided above. It is to be understood that other electrode layers may be used as well, configured with thicknesses that are based on their electrical and acoustic characteristics.

Piezoelectric layers 603 and 605, in various implementations, comprise the same piezoelectric material (e.g., ASN material). Depending on the implementation, piezoelectric layers 603 and 605 may be configured in the same orientation or in different orientations. In an implementation, layer 603 is configured with a reverse c-axis direction relative to that of layer 605. In various embodiments, piezoelectric layers 603 and 605 comprise ASN material, configured in different crystalline orientations, as explained above. For example, with electrode layer 604 disposed between piezoelectric layers 603 and 605, high order thickness extension (TEₙ, n>1) mode can be achieved with desired frequency and bandwidth needs, for specific applications. For example, electrode layer 604 as shown is thinner than piezoelectric layers 603 and 605, but it is to be understood that electrode layer 604 may be thicker, depending on the material used and the implementation.

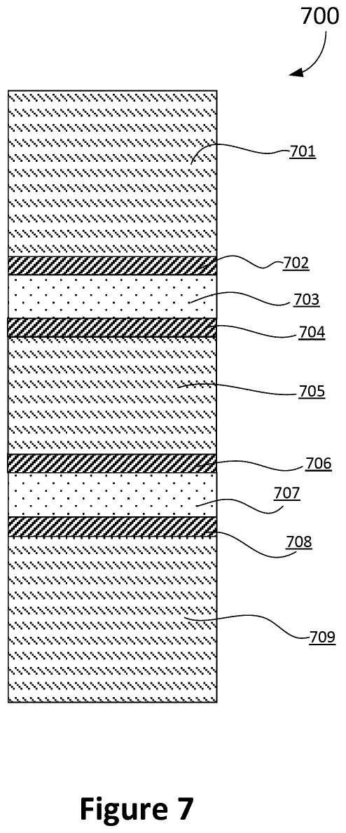

FIG. 7 is a simplified diagram illustrating resonator 700 comprising two piezoelectric layers separated by layers of electrode material according to embodiments of the subject technology. This diagram is merely an example, which should not unduly limit the scope of the claims. One of ordinary skill in the art would recognize many variations, alternatives, and modifications. Resonator 700 includes a top bilayer electrode that includes layer 701 and layer 702. Resonator 700 also includes a bottom bilayer electrode that includes layer 708 and layer 709. Piezoelectric layers 703 and 707 are disposed between the top bilayer electrode and the bottom bilayer electrode. Piezoelectric layers 703 and 707 are separated by three electrode layers 704, 705, and 706. For example, layers 702, 704, 706, and 708—which interface with piezoelectric layers 703 and 707—comprise tungsten material. As an example, of the top electrode, layer 701 comprises aluminum material, and layer 702 comprises tungsten material. Similarly, of the bottom electrode, layer 709 comprises aluminum material, and layer 708 comprises tungsten material. Electrode layers 704, 705, and 706, disposed between two piezoelectric layers respectively comprise tungsten material (layer 704), aluminum material (layer 705), and tungsten material (layer 706) according to an embodiment of the subject technology. Aluminum and tungsten electrode layers—based on their acoustic and electric characteristics—are configured at different thicknesses, as explained above. Aluminum electrode layers are thicker than tungsten electrode layers, for the reasons provided above. It is to be understood that other electrode layers may be used as well, configured with thicknesses that are based on their electrical and acoustic characteristics.

Piezoelectric layers 703 and 707, in various implementations, comprise the same piezoelectric material (e.g., ASN material). Depending on the implementation, piezoelectric layers 703 and 707 may be configured in the same orientation or in different orientations. In an implementation, layer 703 is configured with a reverse c-axis direction relative to that of layer 707. In various embodiments, piezoelectric layers 703 and 707 comprise ASN material, configured in different crystalline orientations, as explained above. For example, with electrode layers 704, 705, and 706 disposed between piezoelectric layers 703 and 707, high order thickness extension (TEₙ, n>1, e.g., TE2, TE3, TE4, etc.) mode can be achieved with desired frequency and bandwidth needs, for specific applications.

While the above is a full description of the specific embodiments, various modifications, alternative constructions and equivalents may be used. Therefore, the above description and illustrations should not be taken as limiting the scope of the subject technology which is defined by the appended claims.

What is claimed is:

1. An acoustic resonator device comprising:
a first electrode characterized by a first thickness, the first electrode comprising a first metal;
a second electrode characterized by a second thickness, the second electrode comprising a second metal; and
a first piezoelectric layer disposed between the first electrode and the second electrode, the first piezoelectric being characterized by a third thickness;
wherein:
a total thickness comprising the first thickness and the second thickness and the third thickness is associated with two or more stress half-waves; and
the acoustic resonator device is characterized by an operating frequency of at least 5 GHz.

2. The acoustic resonator device of claim 1, wherein the first thickness is different from the second thickness.

3. The acoustic resonator device of claim 1, wherein the first thickness is greater than the second thickness, and the first thickness is associated with a first stress half-wave.

4. The acoustic resonator device of claim 1, wherein the total thickness is associated with three stress half-waves.

5. The acoustic resonator device of claim 1, wherein the acoustic resonator device operates in a second thickness extension mode or a third thickness extension mode.

6. The acoustic resonator device of claim 1, wherein:
the first electrode further comprises a third metal, a distance between the first metal and the first piezoelectric layer is greater than a distance between the third metal and the first piezoelectric layer.

7. The acoustic resonator device of claim 6, wherein the first metal is characterized by a first acoustic impedance, the third metal is characterized by a second acoustic impedance, and the second acoustic impedance is greater than the first acoustic impedance.

8. The acoustic resonator device of claim 6, wherein the first metal is characterized by a greater thickness than the third metal.

9. The acoustic resonator device of claim 1, further comprising a second piezoelectric layer disposed between the first electrode and the first piezoelectric layer, the first piezoelectric layer and the second piezoelectric layer being characterized by different orientations;
wherein the total thickness is associated with three or more stress half-waves.

10. An acoustic resonator device comprising:
a first electrode characterized by a first thickness, the first electrode comprising a first metal;
a second electrode characterized by a second thickness, the second electrode comprising a second metal; and
a first piezoelectric layer disposed between the first electrode and the second electrode, the first piezoelectric layer being characterized by a third thickness;
wherein:
a total thickness comprising the first thickness;
the second thickness and the third thickness are associated with two or more stress half-waves; and
the acoustic resonator device operates in a second thickness extension mode or higher.

11. The acoustic resonator device of claim 10, wherein the second thickness extension mode is characterized by an operating frequency of at least 6 GHz.

12. The acoustic resonator device of claim 10, wherein the second electrode further comprises a third metal.

13. The acoustic resonator device of claim 10, further comprising a third electrode and a second piezoelectric layer, the second piezoelectric layer being disposed between the third electrode and the first electrode.

14. An acoustic resonator device comprising:
a first electrode characterized by a first thickness, the first electrode comprising a first metal;
a second electrode characterized by a second thickness, the second electrode comprising a second metal;
a third electrode characterized by a third thickness, the third electrode comprising a third metal;
a first piezoelectric layer disposed between the first electrode and the second electrode, the first piezoelectric being characterized by a fourth thickness; and
a second piezoelectric layer disposed between the second electrode and the third electrode, the second piezoelectric being characterized by a fifth thickness;
wherein the acoustic resonator device operates in a third thickness extension mode or higher.

15. The acoustic resonator device of claim 14, wherein the first metal is characterized by a first acoustic impedance, the second metal is characterized by a second acoustic impedance, and the second acoustic impedance is greater than the first acoustic impedance.

16. The acoustic resonator device of claim 14, wherein the first piezeoelectric layer comprises an aluminum compound.

17. The acoustic resonator device of claim 14, wherein the first thickness is different from the second thickness.

18. The acoustic resonator device of claim 14, wherein the first thickness is greater than the second thickness, and the first thickness is associated with a first stress half-wave.

19. The acoustic resonator device of claim 14, wherein the first piezoelectrical layer is characterized by a different orientation from the second piezoelectrical layer.

20. The acoustic resonator device of claim 14, wherein the first thickness matches the third thickness.
